(19) United States
(12) Patent Application Publication
(10) Pub. No.: US 2006/0049390 A1
(43) Pub. Date: Mar. 9, 2006

(54) Resistively switching nonvolatile memory cell based on alkali metal ion drift

(76) Inventors: Klaus Ufert, Unterschleissheim (DE); Cay-Uwe Pinnow, Munchen (DE); Thomas Happ, Tarrytown, NY (US)

Correspondence Address: EDELL, SHAPIRO & FINNAN, LLC, 1901 RESEARCH BOULEVARD, SUITE 400, ROCKVILLE, MD, 20850, US

(21) Appl. No.: 11/209,026

(22) Filed: Aug. 23, 2005

(30) Foreign Application Priority Data
Aug. 23, 2004 (DE) 10 2004 040 751.7

(51) Int. Cl. H01L 47/00

(52) U.S. Cl. 257/4

(57) ABSTRACT

A nonvolatile, resistively switching memory cell includes a layer arranged between a first electrode and a second electrode. The layer includes one or more chalcogenide compound(s) selected from the group consisting of CuInS, CuInSe, CdInS, CdInSe, ZnInS, MnInS, MnZnInS, ZnInSe, InS, InSSe and InSe, with alkali metal or alkaline-earth metal ions contained in the layer of the chalcogenide compound(s).

### CROSS REFERENCE TO RELATED APPLICATIONS

This application claims priority under 35 USC § 119 to German Application No. 10 2004 040 751.7 filed on Aug. 23, 2004 and titled “Resistively Switching Nonvolatile Memory Cell Based on Alkali Metal Ion Drift,” the entire contents of which are hereby incorporated by reference.

### FIELD OF THE INVENTION

The present invention relates to the field of nonvolatile memories, to a semiconductor element with solid-state ion conductor memory cells, and to a method for fabricating the semiconductor element. In particular, the invention relates to resistively switching memory cells that include a chalcogenide layer as an active layer.

### BACKGROUND

A resistively operating nonvolatile memory cell has at least two different electrical resistances that can be assigned, for example, to the states “0” and “1”. The memory cell may have a higher or lower electrical resistance depending on the applied voltage and can be switched between these two resistances.

One of the main aims in the further development of modem memory technologies is to increase the integration density, which means that it is very important to reduce the feature size of the memory cells on which the memory devices are based.

The technologies used, such as for example DRAM, SRAM or flash memories, have various drawbacks, such as for example volatility (DRAM), size (SRAM) or low endurance (number of possible write/read cycles). Hitherto, there has been no single technology which has been able to satisfy all the requirements for various applications.

Ionic solid-state memories are one of the highly promising technologies for nonvolatile memory cells. By way of example, it is known that certain metals, such as for example silver or copper, can be dissolved in chalcogenide glasses. The term glass is to be understood in the broader sense as meaning in very general terms an amorphous, cooled melt, the atoms of which do not have a continuous long-range order, but rather only a locally limited crystalline arrangement (short-range order) in a three-dimensional unordered network.

One promising approach for the fabrication of resistive nonvolatile memory cells is based on the use of the solid solutions in chalcogenide glasses as active (switching) material for nonvolatile memory cells. A memory cell of this type has a layer of chalcogenide glass arranged between a first electrode and a second electrode; in the simplest case, metal ions of the material forming one of the electrodes are dissolved in the chalcogenide glass.

Chalcogenide glass memory cells are based on an electrochemical redox process, in which metal ions of one electrode can reversibly diffuse into and out of the solid-state electrolyte material, thereby forming or dissolving a low-resistance path. More specifically, the material comprising chalcogenide glasses is arranged between two electrodes, with one electrode being designed as an inert electrode and the other electrode being designed as what is known as a reactive electrode. The ions of the reactive electrode are soluble in the chalcogenide glass.

The chalcogenide glasses are generally semiconductive. The dissolving of the metal ions in the chalcogenide glasses produces a solid solution of the corresponding ions in the glass. Silver ions can, for example, be dissolved by the deposition of an Ag film on a chalcogenide glass and subsequent irradiation. The irradiation of a sufficiently thick Ag film on Ge₃Se₇ produces, for example, a material of formula Ag_{0,33}Ge_{0,20}Se_{0,47}. Accordingly, the solutions may form by the photo-dissolution of silver in, for example, As₂S₃, AsS₂, GeSe₂.

An arrangement including an inert electrode of molybdenum or gold, a second electrode of silver and a layer of a chalcogenide glass of As₂S₃ photo-doped with Ag⁺ ions arranged between the two electrodes is described in Hirose et al., Journal of Applied Physics, Vol. 47, No. 6, 1976, pp. 2767 to 2772, “Polarity-dependent memory switching and behavior of Ag dendrite in Ag-photodoped amorphous As₂S₃ films.” Applying a positive voltage to the Ag electrode, which must be higher than what is known as a minimum threshold voltage, oxidizes the electrode, forces the Ag⁺ ions into the chalcogenide glass and reduces them again on the inert electrode, which leads to metallic deposits in the form of a conductive Ag path (dendrites) between the first and second electrodes. This lowers the electrical resistance of the arrangement. In this state, the electrical resistance of the solid-state electrolyte is reduced significantly (for example by several orders of magnitude) compared to the state without a metallic current path, thereby defining the ON state of the memory cell. If an oppositely polarized voltage is applied to the two electrodes, this leads to the formation of the metallic deposits or the current path being reversed, with the result that the two electrodes are no longer continuously electrically connected to one another, thereby defining the OFF state of the memory cell, since in this state the memory cell has a higher resistance than in the ON state.

Therefore, the general mechanism can be explained as being that the reactive electrode together with the solid-state electrolyte forms a redox system in which a redox reaction takes place above a defined threshold voltage (Vₜₕ). Depending on the polarity of the voltage which is applied to the two electrodes, although this voltage must be higher than the threshold voltage, the redox reaction can take place in one reaction direction or the other. Depending on the applied voltage, the reactive electrode is oxidized and the metal ions of the reactive electrode diffuse into the chalcogenide glass and are reduced at the inert electrode. If metal ions are being continuously released into the solid-state electrolyte, the number and size of the metallic deposits increase until ultimately a metallic current path which bridges the two electrodes is formed (ON state). If the polarity of the voltage is reversed, metal ions diffuse out of the chalcogenide glass and are reduced at the reactive electrode, which causes the metallic deposits located on the inert electrode to break down. This process is continued under the influence of the applied voltage until the metallic deposits which form the electrical path have been completely broken down (OFF state). The electrical resistance of the OFF state is 2 to 6 orders of magnitude greater than the resistance of the ON state. The memory concept based on the mechanism described above is known as a CB (conductive bridge) memory cell.

The implementation of individual switching elements which are based on chalcogenide glasses, such as As₂S₃, GeSe or GeS and WOₓ, is known and published, e.g., in M. N. Kozicki et al., “Superlattices and Microstructures”, Vol. 27, No. 5/6, 2000, pp. 485 to 488, M. N. Kozicki et al., Electrochemical Society Proceedings, Vol. 99-13, 1999, pp. 298 to 309, “Applications of Programmable Resistance Changes in Metal-Doped Chalcogenides” and M. N. Kozicki et al., 2002, “Can Solid State Electrochemistry Eliminate the Memory Scaling Quandary?”

The above-referenced publications propose depositing the solid-state electrolyte in a via hole (a hole between two metallization levels of a semiconductor element) which has been etched vertically in a conventional inter-dielectric. Then, the material of the reactive electrode is deposited and patterned, for example, by a suitable etching process or by chemical mechanical polishing (CMP). This is followed by a process that drives the material of the reactive electrode into the solid-state electrolyte in order to generate background doping of the solid-state electrolyte with the metal of the reactive electrode by UV irradiation.

However, the implementation of the memory cells based on the abovementioned chalcogenide materials brings with it serious problems, for example, the fact that the limited thermal stability of the chalcogenide glasses requires special measures for back-end integration of a fully integrated memory. By way of example, Se-rich GeSe has a phase change at just 212° C., which throws up serious problems in particular for processing in the back-end sector (e.g., see Gokhale et al., Bull. Alloy Phase Diagrams 11 (3), 1990).

The production of chalcogenide layers is known per se and can be achieved by conventional techniques. By way of example, it is known to produce the chalcogenide glasses by evaporation coating processes (see, e.g., Petkova et al., Thin Solid Films 205 (1991), 205; and Kozicki et al., Superlattices and Microstructures, Vol. 27, No. 5/6 (2000) 485-488) or by a sputtering process using suitable sputtering targets, such as for example by multi-source deposition (see E. Broese et al., Journal of Non-Crystalline Solids (1991), Vol. 130, No. 1, p. 52-57), alloying targets (see Moore et al., Physics of Non-Crystalline Solids, Taylor & Francis, London, UK, 1992, p. 193-197, xvi+761 pp7 ref.; Conference: Moore et al.: Conference paper (English), Cambridge, UK, 4-9 Aug. 1991 ISBN 0-7484-0050-8, M. W.; and France et al., Sputtering of Chalcogenide coatings on the fluoride glass) or by a multi-component target (Choi et al., Journal of Non-Crystalline Solids Elsevier: 1996, Vol. 198-200, pt. 2, p. 680-683; Conference: Kobe, Japan 4-8 Sep. 1995 SICI: 0022-3093 (1995605) 198/200: 2L. 680: OPSU, 1-8 ISSN 0022-3093 Conference paper (English), p Optical properties and structure of unhydrogenated, hydrogenated, and zinc-alloyed GexSel-x films prepared by radiofrequency sputtering). Since the compounds of the composition MₘX₁₋ₘ are completely miscible in the amorphous phase over the concentration range, it is possible to determine the composition by suitable selection of the material or sputtering target which is to be vaporized. The most important of these processes is sputtering deposition of these binary chalcogenide layers (e.g. Ge—Se or Ge—S) from a binary mixed target.

One drawback of the memory cells based on chalcogenide glasses as active material is that all the memory cells which have been described hitherto have to include ions of one of the electrodes (in most cases Ag⁺ ions) in the chalcogenide matrix. This fact restricts the choice of material to be used considerably and also means that ions (e.g., Ag⁺ ions) have to be dissolved in the chalcogenide matrix in a complex photodiffusion process step.

### SUMMARY

An object of the invention is to provide a nonvolatile, resistive memory cell with an active storage layer including a chalcogenide matrix, without the ions of one of the electrodes being contained in this matrix.

A further object of the invention is to provide a method for fabricating such a resistive memory cell.

Yet another object of the invention is to provide materials that can be used as a matrix or storage layer for nonvolatile memory cells.

The aforesaid objects are achieved individually and/or in combination, and it is not intended that the present invention be construed as requiring two or more of the objects to be combined unless expressly required by the claims attached hereto.

In accordance with the present invention, a nonvolatile, resistively switching memory cell comprises a layer arranged between a first electrode and a second electrode, where the layer includes one or more chalcogenide compound(s) selected from the group consisting of CuInS, CuInSe, CdInS, CdInSe, ZnInS, MnInS, MnZnInS, ZnInSe, InS, InSSe and InSe, with alkali metal or alkaline-earth metal ions contained in the layer of the chalcogenide compound(s).

The above and still further objects, features and advantages of the present invention will become apparent upon consideration of the following detailed description of specific embodiments thereof, particularly when taken in conjunction with the accompanying drawings where like numerals designate like components.

### BRIEF DESCRIPTION OF THE DRAWINGS

FIG. 1 depicts a diagrammatic cross section through a memory cell in accordance with the invention;

FIG. 2 depicts a diagrammatic cross section through a memory cell in accordance with a further embodiment of the invention;

FIG. 3 depicts a diagrammatic cross section through a memory cell in accordance with a still another embodiment of the invention.

### DETAILED DESCRIPTION

In accordance with the present invention, a nonvolatile, resistively switching memory cell includes a layer arranged between a first electrode and a second electrode, where the layer includes one or more chalcogenide compound(s) selected from the group consisting of CuInS, CuInSe, CdInS, CdInSe, ZnInS, MnInS, MnZnInS, ZnInSe, InS, InSSe and InSe, with alkali metal or alkaline-earth metal ions contained in the layer of the chalcogenide compound(s).

The memory cell according to the invention is not based on the storage of charges, but rather on the difference in resistance between two stable states caused by the high mobility of alkali metal or alkaline-earth metal ions in the active layer of defined chalcogenide compounds according to the invention when an electric field is applied.

Chalcogenide glasses based on CuInS, CuInSe, CdInS, CdInSe, ZnInS, MnInS, MnZnInS, ZnInSe, InS, InSSe and InSe are used as a storage layer in accordance with the invention, since these compounds have a particularly open network structure, so that channels that allow good and rapid ion conduction exist in the structural interstices even at room temperature. Unlike oxidic networks, the open networks are formed with S or Se ions which, on account of their larger dimensions, have an anionic network with a high polarizability. This additionally facilitates the ion movement (drift) of the alkali metal or alkaline-earth metal ions through the networks. In addition to the greater mobility of the alkali metal or alkaline-earth metal ions in the storage layers according to the invention, which consist of negative ion networks, these negative ion networks also allow a higher uptake and therefore a greater concentration of alkali metal or alkaline-earth metal cations.

One major advantage of the memory cells according to the invention over the CB memory cells is that the matrix material of the active layer is chemically inert with respect to the ions, so that it is impossible for a chemical compound to form between the matrix and the ions dissolved therein. Thus, the physical properties of the system are not influenced by chemical processes, such as for example precipitation of the matrix material with the alkali metal or alkaline-earth metal ions, and consequently can be more deliberately optimized.

A further advantage of the memory cells according to the invention is that, unlike when using the Ge—Se:Ag or Ge—S:Ag memory types (CB memories), there is no need for an additional photodiffusion process step which has to be used to make the silver which has previously been deposited on the matrix diffuse into the Ge—Se or Ge—S matrix by UV irradiation. In the system according to the invention, the alkali metal or alkaline-earth metal ions are advantageously deposited in one process step together with the chalcogenide glass, for example by magnetron sputtering of a suitable compound target.

In one particular embodiment, the nonvolatile, resistively switching memory cells according to the invention have, in accordance with the invention, a first and/or a second electrode composed of a material selected from the group consisting of molybdenum, tantalum, copper, aluminum, silver, gold, tungsten, titanium, titanium nitride, platinum, tantalum, tantalum nitride, and carbon. Particularly preferred electrode materials for both electrodes are tungsten (W), molybdenum (Mo) and titanium (Ti).

The storage mechanism according to the invention is based on the mobility of alkali metal or alkaline-earth metal ions in a chemically inert, high-resistance matrix which can be scaled down to nanometer dimensions. Starting from an accumulation of the mobile alkali metal or alkaline-earth metal ions in a region with a high concentration in the matrix close to a thermally stable, chemically inert metal electrode made, for example, from Mo or W, the memory cell is in a high-resistance state. The application of a negative voltage pulse to the counter-electrode accelerates the alkali metal or alkaline-earth metal ions through the high-resistance chalcogenide diffusion matrix toward the counter-electrode. This leads to a state with an electrical resistance that is typically two orders of magnitude lower.

In a preferred embodiment of the invention, the nonvolatile, resistively switching memory cell according to the invention has a concentration gradient of the alkali metal or alkaline-earth metal ions in the chalcogenide layer.

In a further embodiment of the invention, the nonvolatile, resistively switching memory cell according to the invention has a double layer, arranged between two electrodes, comprising a first layer and a second layer including the chalcogenide compound(s) selected from the group consisting of CuInS, CuInSe, CdInS, CdInSe, ZnInS, MnInS, MnZnInS, ZnInSe, InS, InSSe and InSe. In this embodiment, the first and second layers have different concentrations of the alkali metal or alkaline-earth metal ions.

In a preferred embodiment of the invention, the nonvolatile, resistively switching memory cell according to the invention has a double layer, arranged between two electrodes, comprising a first layer and a second layer including the chalcogenide compound(s), with one of the layers not including any alkali metal or alkaline-earth metal ions.

In an alternative embodiment, the first layer is lightly doped with alkali metal or alkaline-earth metal ions and the second layer is heavily doped with alkali metal or alkaline-earth metal ions.

The preferred alkali metal ions which are dissolved in the chalcogenide matrix are Na⁺ ions.

The preferred chalcogenide compound for the active layer is a CuInS compound.

The arrangements described above can be realized in horizontal or vertical implementations on a semiconductor, and the orientation is independent of the electrode material and the choice of chalcogenide compound.

The invention further includes a method that is particularly suitable for the fabrication of the nonvolatile, resistive memory cell according to the invention. In the method according to the invention, the first electrode layer is deposited preferably by conventional sputtering or any other desired process (e.g. evaporation coating, CVD, PLD or ALD processes). This material is introduced into a hole which has previously been etched and then planarized by means of CMP (chemical mechanical polishing). Alternative patterning processes, such as deposition and subsequent etching, can also be used in a similar manner. Subsequently, the first electrode produced in this manner is coated with a dielectric and a hole is etched through this dielectric, so that chalcogenide material doped with alkali metal or alkaline-earth metal ions which is subsequently deposited is in direct electrical contact with the electrode layer.

The chalcogenide material for the embodiment in which there is a double layer of the chalcogenide material can be deposited by sputtering processes or, for example, by CVD or ALD processes. For the previously noted reasons, it is advantageous to select an alkali metal ion doping and in particular sodium doping. This step also icludes the multiple chalcogenide layer deposition with different alkali metal or alkaline-earth metal ion concentrations mentioned in the embodiment with the double layer.

In one particularly preferred embodiment, the deposition of the chalcogenide layer is followed by an RTP (Rapid Thermal Processing) step, in which the chalcogenide material is treated in a selenium-containing or sulphur-containing atmosphere in order to achieve the open structure of the chalcogenide material which is required for memory operation. The structure produced in this way can be completed by CMP processes or etching and subsequent deposition of the second electrode.

To prevent the alkali metal or alkaline-earth metal ions from diffusing laterally out of the matrix material into the surrounding layers, a diffusion barrier, for example of silicon nitride or silicon oxynitride, is provided.

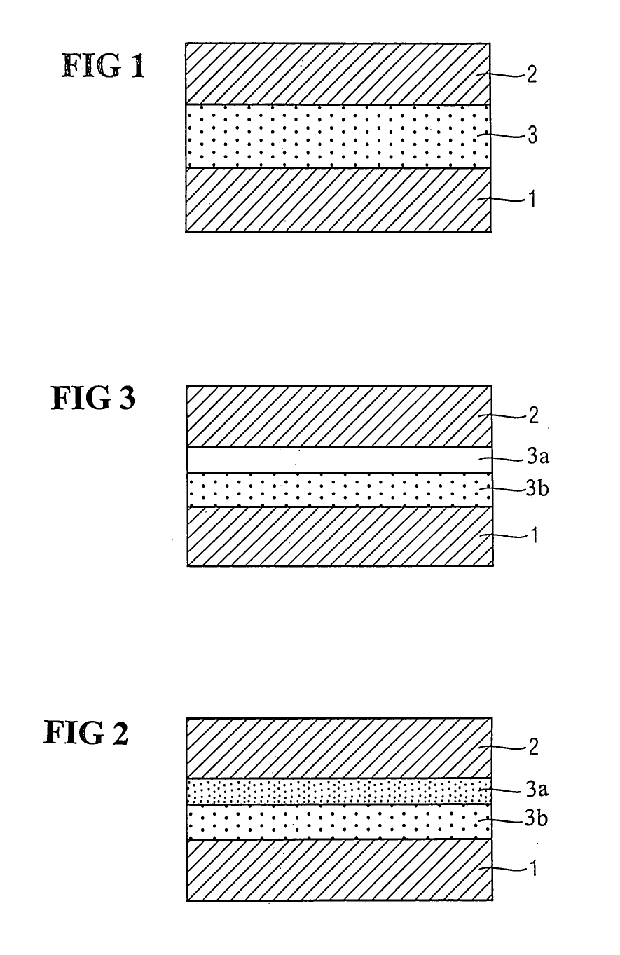

Exemplary embodiments of the invention will now be described with reference to FIGS. 1-3.

In a first embodiment according to the invention and as depicted in FIG. 1, a chalcogenide layer (3) doped with alkali metal ions is formed between a first electrode (1) and a second electrode (2). The chalcogenide layer (3) includes one or more chalcogenide compound(s) selected from the group consisting of CuInS, CuInSe, CdInS, CdInSe, ZnInS, MnInS, MnZnInS, ZnInSe, InS, InSSe and InSe or of an alloy of the abovementioned compounds. This chalcogenide layer is doped with alkali metal or alkaline-earth metal ions and can have a concentration gradient of the alkali metal or alkaline-earth metal ions between the first and second electrodes by virtue of an inhomogeneous doping.

FIG. 2 illustrates a further embodiment, in which the chalcogenide layer (3) includes a double layer 3a and 3b. In the arrangement shown in FIG. 2, the layer (3a) is only lightly doped with alkali metal or alkaline-earth metal ions, whereas the layer (3b) is heavily doped with alkali metal or alkaline-earth metal ions. The first electrode (1) and the second electrode (2) preferably include a high-melting material, such as for example tungsten, molybdenum or titanium.

FIG. 3 shows an embodiment in which the double layer includes two chalcogenide layers 3a and 3b, with one of the layers 3a not containing any alkali metal or alkaline-earth metal ions.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### REFERENCE LIST

1 first electrode
2 second electrode
3 chalcogenide layer(s)

What is claimed:

1. A nonvolatile, resistively switching memory cell comprising a first electrode, a second electrode, and a layer arranged between the first and second electrodes, wherein the layer includes at least one chalcogenide compound or an alloy thereof selected from the group consisting of CuInS, CuInSe, CdInS, CdInSe, ZnInS, MnInS, MnZnInS, ZnInSe, InS, InSSe, and InSe, and the layer further includes alkali metal or alkaline-earth metal ions.

2. The nonvolatile, resistively switching memory cell of claim 1, wherein at least one of the first and second electrodes includes at least one of molybdenum, tantalum, tantalum nitride, copper, aluminum, silver, gold, tungsten, titanium, titanium nitride, platinum, and carbon.

3. The nonvolatile, resistively switching memory cell of claim 1, wherein the layer includes a concentration gradient of the alkali metal ions or alkaline-earth metal ions.

4. The nonvolatile, resistively switching memory cell of claim 1, wherein the layer includes a first layer and a second layer, and at least one of the first and second layers includes alkali metal ions or alkaline-earth metal ions.

5. The nonvolatile, resistively switching memory cell of claim 4, wherein one of the first layer and the second layer does not include any alkali metal ions or alkaline-earth metal ions.

6. The nonvolatile, resistively switching memory cell of claim 4, wherein the first and second layers include different concentrations of alkali metal ions or alkaline-earth metal ions.

7. The nonvolatile, resistively switching memory cell of claim 1, wherein the layer includes alkali metal ions comprising Na⁺ ions.

8. The nonvolatile, resistively switching memory cell of claim 1, wherein the chalcogenide compound is a CuInS compound.

9. A method for fabricating a nonvolatile, resistive memory cell comprising:
forming a first electrode;
depositing a layer over the first electrode, the layer comprising at least one chalcogenide compound selected from the group consisting of CuInS, CuInSe, CdInS, CdInSe, ZnInS, MnInS, MnZnInS, ZnInSe, InS, InSSe, and InSe;
doping the layer with alkali metal or alkaline-earth metal ions; and
depositing a second electrode over the layer.

10. The method of claim 9, wherein at least one of the first and second electrodes includes at least one of molybdenum, tantalum, tantalum nitride, copper, aluminum, silver, gold, tungsten, titanium, titanium nitride, platinum, and carbon.

11. The method of claim 9, wherein the layer of the chalcogenide compound, after the doping with alkali metal or alkaline-earth metal ions, has a concentration gradient of the alkali metal ions or alkaline-earth metal ions.

12. The method of claim 9, wherein the layer includes a first layer and a second layer, wherein each of the first and second layers comprises at least one chalcogenide compound selected from the group consisting of CuInS, CuInSe, CdInS, CdInSe, ZnInS, MnInS, MnZnInS, ZnInSe, InS, InSSe, and InSe.

13. The method of claim 12, wherein at least one of the first and second layers includes alkali metal ions or alkaline-earth metal ions.

14. The method of claim 12, wherein one of the first layer and the second layer does not include any alkali metal ions or alkaline-earth metal ions.

15. The method of claim 12, wherein the first and second layers include different concentrations of the alkali metal or alkaline-earth metal ions.

16. The method of claim 9, wherein at least one of the first and second electrodes is deposited by one of a sputtering process, an evaporation coating process, a CVD process, and an ALD process.

17. The method of claim 9, wherein the layer is deposited by one of a sputtering process, a CVD process, and an ALD process.

18. The method of claim 9, wherein the layer is doped with alkali metal ions comprising Na⁺ ions.

19. The method of claim 9, wherein the layer includes a CuInS compound.
